(19) United States
(12) Patent Application Publication
(10) Pub. No.: US 2023/0253189 A1
(43) Pub. Date: Aug. 10, 2023

(54) SEAL VENTING IN A SUBSTRATE PROCESSING CHAMBER

(71) Applicant: Lam Research Corporation, Fremont, CA (US)

(72) Inventors: Hui Ling Han, Alameda, CA (US); Michael Julius Kinsler, San Jose, CA (US); Steven James Madsen, San Leandro, CA (US); Gabriel Pioux, Davis, CA (US)

(21) Appl. No.: 18/013,737

(22) PCT Filed: Jun. 30, 2021
(86) PCT No.: PCT/US2021/039981

§ 371 Date: Dec. 29, 2022

Related U.S. Application Data
(60) Provisional application No. 63/051,253, filed on Jul. 13, 2020.

(51) Int. Cl. H01J 37/32

(52) U.S. Cl. CPC H01J 37/32513; H01J 2237/334

(57) ABSTRACT

In some examples, a double seal arrangement for a substrate processing chamber comprises a radially inner barrier seal disposed within a barrier seal gland. The barrier seal gland includes an inner toe and an outer toe. A radially outer vacuum seal is disposed within a vacuum seal gland. The vacuum seal gland includes at least an inner toe. A first venting pathway is provided between the inner toe of the vacuum seal gland and the outer toe of the barrier seal gland, and a second venting pathway is provided between the outer toe of the barrier seal gland and the inner toe of the barrier seal gland. A third venting pathway is in communication at least with the inner toe of the barrier seal gland, and a vacuum source connected to at least one of the first, second, and third venting pathways.

### CLAIM OF PRIORITY

This application claims the benefit of priority to U.S. Provisional Patent Application Ser. No. 63/051,253, filed on Jul. 13, 2020, which is incorporated by reference herein in its entirety.

### FIELD

The present disclosure relates generally to systems, apparatus, and methods for seal venting in substrate processing chambers, and more particularly to the venting of barrier and vacuum seal arrangements therein.

### BACKGROUND

Conventional vacuum seal arrangements in substrate processing chambers may suffer from so-called “virtual leaks”. A virtual leak can occur when internally trapped air appears to “leak” towards a vacuum source or chamber, as opposed to being derived from an external source of air that enters through a “real” hole or leak in the chamber somewhere. It will be appreciated that, whether virtual or not, a leak can impair the effectiveness of a vacuum seal. In more extreme cases, a virtual leak can defeat the purpose of a vacuum system, which is to achieve vacuum and prevent the intrusion of atmospheric gas into the process volume.

In single vacuum seal arrangements, air can become trapped on a bottom vacuum-side area (or toe) of the seal gland (or groove) in which the vacuum seal sits. In a double-seal arrangement, air can become trapped in both toes of the barrier-seal gland, the inner toe of the vacuum-seal gland, and in the space between the two seals. The trapped air can give rise to virtual leaks.

The background description provided herein is to generally present the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

The present disclosure relates generally to systems, apparatus, and methods for seal venting in substrate processing chambers, and more particularly to the venting of double seal arrangements therein. In some aspects, the present disclosure relates to techniques for venting certain vacuum-seal interfaces to reduce or prevent the occurrence of virtual leaks. In some examples, these techniques may be applied at component interfaces at which a separate chemically-resistant seal is used to shield a primary vacuum seal from process chemistry such as aggressive plasma gases and the like. At the top of a vacuum chamber, for example, an example interface may include two concentric O-ring face seals, the inner seal presenting a barrier to the process chemistry and the outer being the vacuum seal. The purpose of this double-seal arrangement is to enable the use of more cost effective or higher performing vacuum seals by decoupling the function of chemical resistance from the function of providing a vacuum seal.

Oxygen radicals are an example of process chemistry components that can be highly damaging to vacuum seals. One aspect of this disclosure is to provide a venting arrangement which creates such a venting passage that process chemistry (for example, the oxygen radicals) are unable to travel backstream (against the direction of applied vacuum) to the vacuum seal. The more collisions the radicals undergo, the more likely they are to recombine. In some examples, the number of collisions through a venting pathway path is proportional to the cross-sectional size, length, and tortuousness of the path. In some examples, one or more venting pathways are provided to establish a venting passageway that is sufficiently constrictive, long and tortuous that the probability of radicals reaching the vacuum seal before recombination becomes exceedingly low.

In some examples, a double seal arrangement for a substrate processing chamber is provided. An example double seal arrangement comprises a radially inner barrier seal disposed within a barrier seal gland, the barrier seal gland including an inner toe and an outer toe; a radially outer vacuum seal disposed within a vacuum seal gland; the vacuum seal gland including at least an inner toe; a first venting pathway between the inner toe of the vacuum seal gland and the outer toe of the barrier seal gland; a second venting pathway between the outer toe of the barrier seal gland and the inner toe of the barrier seal gland; a third venting pathway in communication at least with the inner toe of the barrier seal gland; and a vacuum source connected to at least one of the first, second, and third venting pathways.

In some examples, the second venting pathway includes a cross channel passing underneath the barrier seal.

In some examples, the first and second vent pathways include or are defined by a common cross channel extending between the vacuum seal gland and the barrier seal gland, the cross channel passing underneath a lower surface of the barrier seal at a first circumferential location of the barrier seal gland.

In some examples, a dimension of the cross channel prevents closure thereof by the harrier seal when the double seal arrangement is under vacuum.

In some examples, the cross channel includes a recess permitting access by a machining tool into the barrier seal gland during formation of the cross channel.

In some examples, the third venting pathway includes or is defined by a venting port provided at a second circumferential location of the harrier seal gland.

In some examples, the first and second venting pathways are provided at a common location, and the third venting pathway is provided at a separate location.

In some examples, the second and third venting pathways are provided at a common location, and the first venting pathway is provided at a separate location.

In some examples, the first, second and third venting pathways are each provided at a separate location.

In some examples, the first and second venting pathways are provided at respective separate locations on the respective barrier and vacuum seal glands.

In some examples, the third venting pathway is provided at a respective separate location with respect to the first and second venting pathways.

In some examples, the vacuum source includes or is generated by the processing chamber.

In some examples, the vacuum source includes an exhaust line of the processing chamber.

In some examples, the vacuum source includes an external vacuum source.

In some examples, the double seal arrangement further comprises a vacuum retarding means disposed in any one or more of the first, second, and third venting pathways.

In some examples, the vacuum retarding means includes a thread screw or tortuous path.

In some examples, a wall of the barrier seal gland or the vacuum seal gland includes an anodized aluminum material.

In some examples, an apparatus for providing a double seal arrangement for a substrate processing chamber is provided. An example apparatus comprises a radially inner barrier seal gland for receiving a barrier seal therein, the barrier seal gland including an inner toe and an outer toe; a radially outer vacuum seal gland for receiving a vacuum seal therein, the vacuum seal gland including at least an inner toe; a first venting pathway between the inner toe of the vacuum seal gland and the outer toe of the harrier seal gland; a second venting pathway between the outer toe of the barrier seal gland and the inner toe of the barrier seal gland; and a third venting pathway between the inner toe of the barrier seal gland and a vacuum source.

In some examples, the apparatus is defined by a single component.

In some examples, the apparatus is defined by multiple components.

In some examples, the apparatus further comprises a barrier seal and a vacuum seal.

In some examples, a processing chamber is proved. An example chamber comprises a double seal arrangement, the double seal arrangement comprising: a radially inner barrier seal disposed within a barrier seal gland, the barrier seal gland including an inner toe and an outer toe; a radially outer vacuum seal disposed within a vacuum seal gland, the vacuum seal gland including at least an inner toe; a first venting pathway between the inner toe of the vacuum seal gland and the outer toe of the barrier seal gland; a second venting pathway between the outer toe of the barrier seal gland and the inner toe of the barrier seal gland, a third venting pathway in communication at least with the inner toe of the barrier seal gland; and a vacuum source connected to at least one of the first, second, and third venting pathways.

### BRIEF DESCRIPTION OF THE SEVERAL VIEWS OF THE DRAWINGS

Some embodiments are illustrated by way of example and not limitation in the views of the accompanying drawings.

FIG. 1 is a schematic diagram of a reaction chamber within which some embodiments of the present gas distributor may be employed.

FIG. 2 illustrates an arrangement in accordance with one embodiment.

FIGS. 3A-3B respectively illustrate pictorial and part-sectional views of a substrate processing chamber in accordance with one embodiment.

FIG. 4 illustrates a double seal arrangement in accordance with one embodiment.

FIG. 5 illustrates a part sectional view of a processing chamber in accordance with one embodiment.

FIG. 6 illustrates a pictorial view of aspects of a double seal arrangement in accordance with one embodiment.

FIG. 7 illustrates a sectional view of aspects of a double seal arrangement in accordance with one embodiment.

FIG. 8 illustrates a pictorial view of aspects of a double seal arrangement in accordance with one embodiment.

FIG. 9 illustrates a sectional view of aspects of a double seal arrangement in accordance with one embodiment.

FIG. 10 includes perspective views of a cover plate in accordance with one embodiment.

### DETAILED DESCRIPTION

The description that follows includes systems, arrangements, methods, techniques, and computing machine program products that embody illustrative embodiments of the present disclosure. In the following description, for purposes of explanation, numerous specific details are set forth in order to provide a thorough understanding of example embodiments. It will be evident, however, to one skilled in the art that the present disclosure may be practiced without these specific details.

A portion of the disclosure of this patent document may contain material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to any data as described below and in the drawings that form a part of this document: Copyright Lam Research Corporation, 2020, All Rights Reserved.

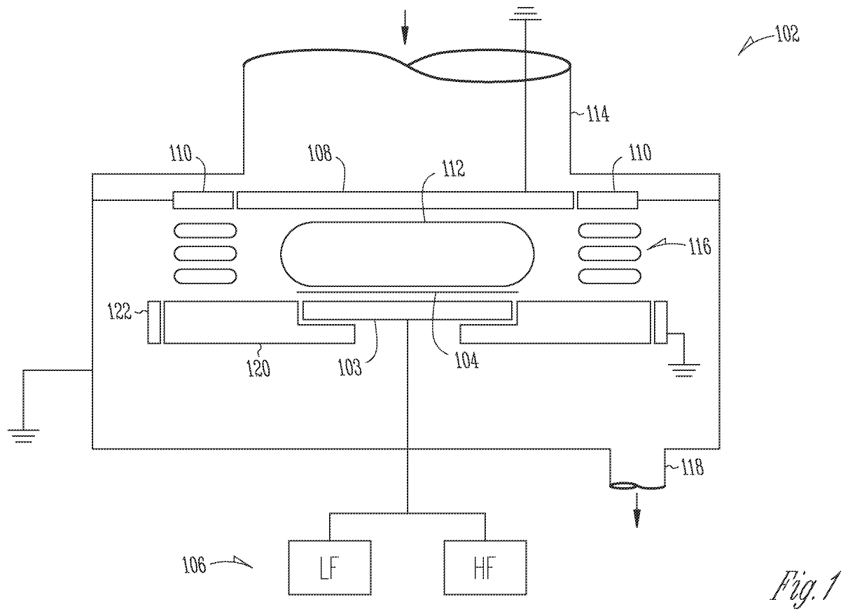

FIG. 1 is a schematic diagram of a reaction chamber within which some embodiments of the present gas distributor may be employed. FIG. 1 illustrates a capacitively-coupled plasma processing chamber 102, representing an exemplary plasma processing chamber of the types typically employed to etch a substrate. The processing chamber 102 includes a chuck 103, representing the workpiece holder on which a substrate, such as a wafer 104, is positioned during etching. The chuck 103 may be implemented by any suitable chucking technique, e.g., electrostatic, mechanical, clamping, vacuum, or the like. During etching, the chuck 103 is typically supplied with dual RF frequencies ( a low frequency and high frequency), for example 2 MHz and 27 MHz, simultaneously, during etching by a dual-frequency power source 106.

An upper electrode 108 is located above the wafer 104. The upper electrode 108 is grounded. FIG. 1 illustrates an etching reactor where the surface of the upper electrode 108 is larger than the surface of the chuck 103 and the wafer 104. During etching, plasma 112 is formed from etchant source gas supplied via a gas line 114 and pumped out through an exhaust line 118. The processing chamber 102 may thus be under vacuum. Within the processing chamber 102, the gas line 114 may be connected to a showerhead (not shown).

An electrical insulator ring 110 insulates the upper electrode 108 from the processing chamber 102. Confinement rings 116 may be placed between the upper electrode 108 and a bottom electrode, such as the chuck 103 in FIG. 1. In general, the confinement rings 116 help confine the etching plasma 112 to the region above the wafer 104 to improve process control and to ensure repeatability.

When RF power is supplied to chuck 103 from the dual-frequency power source 106, equipotential field lines are set up over wafer 104. The equipotential field lines are the electric field lines across the plasma sheath that is between wafer 104 and the plasma 112. During plasma processing, the positive ions accelerate across the equipotential field lines to impinge on the surface of wafer 104, thereby providing the desired etch effect, such as improving etch directionality. Due to the geometry of the upper electrode 108 and the chuck 103, the field lines may not be uniform across the wafer surface and may vary significantly at the edge of the wafer 104. Accordingly, a focus ring 120 is typically provided to improve process uniformity across the entire wafer surface. With reference to FIG. 1, the wafer 104 is shown disposed within a focus ring 120, which may be formed of a suitable dielectric material such as ceramic, quartz, plastic, or the like. Thus, the presence of the focus ring 120 allows the equipotential field lines to be disposed substantially uniformly over the entire surface of the wafer 104.

An electrically conductive shield 122 substantially encircles the focus ring 120. The electrically conductive shield 122 is configured to be substantially grounded within the plasma processing chamber 100. The conductive shield 122 prevents the presence of unwanted equipotential field lines outside of focus ring 120. In relation to the chamber source gas supplied via the mixed gas line 114, it has been found that the gas transport characteristics within the plasma reactor and upstream of it can be the most sensitive variables contributing to etch or deposition non-uniformities.

As mentioned above, conventional vacuum seal arrangements in substrate processing chambers may suffer from so-called “virtual leaks”. A virtual leak can occur when internally trapped air appears to “leak” towards a vacuum source or chamber, as opposed to being derived from an external source of air that enters through a “real” hole or leak in the chamber somewhere. It will be appreciated that, whether virtual or not, a leak can negatively affect, if not completely destroy, the effectiveness of a vacuum seal.

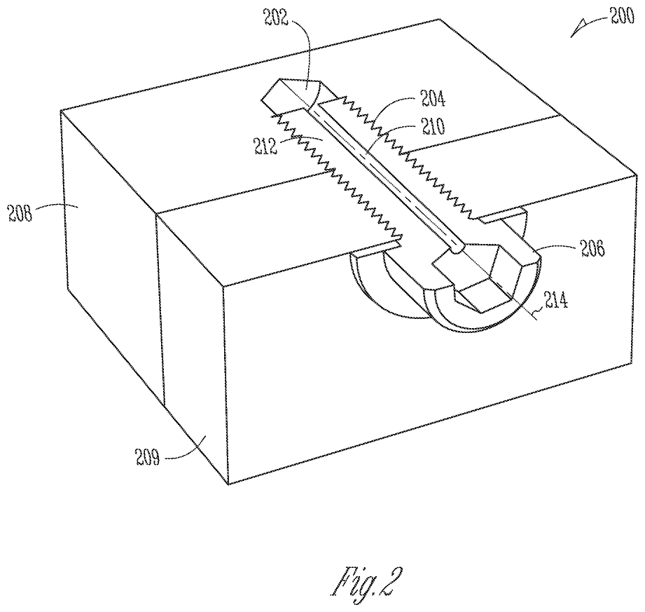

FIG. 2 illustrates an example assembly 200 that addresses a virtual leak situation. Gases can become trapped in blind tapped hole 202. In a conventional threaded screw 204, these gases would leak out through the threads over time and escape under the head 206 of the threaded screw 204, thus causing a “virtual leak”. Although there is no actual or real leak through the connected walls 208 and 209, the slow release of trapped air from a multiplicity of threaded screws 204 can significantly impair any ability to maintain a consistent vacuum pressure on the head end of the threaded screw 204 in the wall 209. In one example situation, the entire assembly 200 may be contained within a larger vacuum chamber, such as the processing chamber 102. In another example situation, the inner wall 209 (with respect to the screw head 206) of the assembly 200 may be positioned entirely within a vacuum zone bounded by a vacuum chamber of which the outer wall 208 forms an integral part.

In the illustrated example, a vented threaded screw 204 is provided. The vented threaded screw 204 includes a center bore 210 or vent that spans the length of the threaded screw 204 from head 206 to shank 212. The trapped gases and air can escape through the bore 210 at 214.

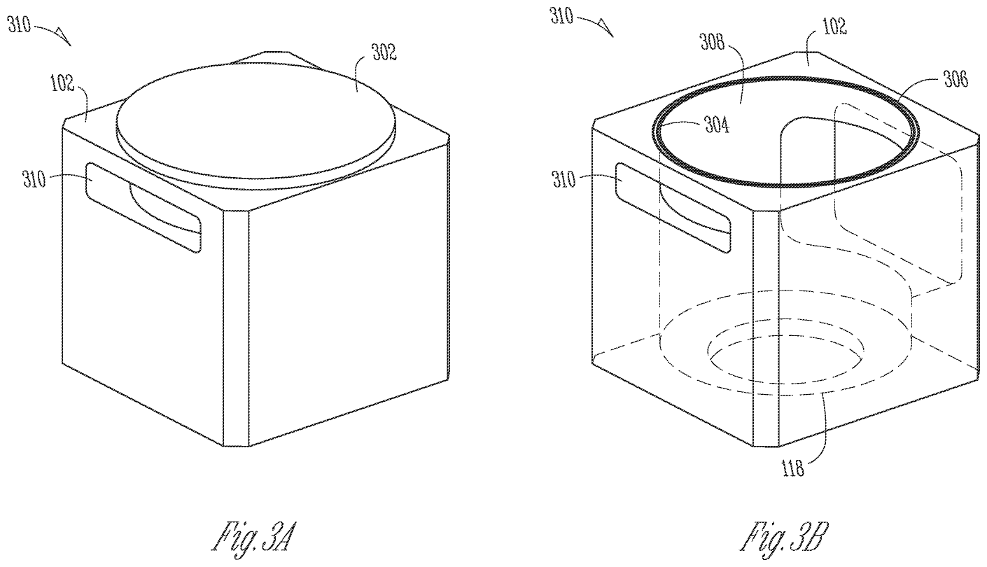

FIGS. 3A-3B respectively illustrate pictorial and part-sectional views of a substrate processing chamber, such as a processing chamber 102 of FIG. 1. Certain parts are shown in ghosted outline in FIG. 3B. The processing chamber 102 includes a cylindrical side wall 308, which is in communication with a loading port 310 to admit a substrate (for example, wafer 104) into the processing chamber 102. The processing chamber 102 may be under vacuum and act as a vacuum chamber. To this end, an underside of the processing chamber 102 may be connected directed or indirectly to an external vacuum source, for example a vacuum pump connected to exhaust line 118 (as depicted in FIG. 1 and FIG. 3B). The top of the processing chamber 102 or vacuum chamber is covered by a cover plate 302 (FIG. 3A). An interface between the cover plate 302 and the processing chamber 102 includes a double seal arrangement, as shown. The double seal arrangement includes two concentric O-ring face seals. In some examples, the inner seal presents a barrier to substrate processing chemistry in the processing chamber 102, while the outer seal acts as a vacuum seal. The inner seal is referred to herein as a barrier seal 304. The outer seal is referred to herein as a vacuum seal 306. Other terminology may be used.

In some examples, the purpose of the double seal arrangement is to enable the use of more cost effective or higher performing vacuum seals by relieving them of the burden of requiring one seal that functions as bath a chemical barrier as well as a vacuum seal. In other words, the function of providing chemical resistance is decoupled from the function of providing a vacuum seal. As discussed above, double seal arrangements may result in the capture of a non-negligible volume of trapped air at the bottom radii of the seal glands (also referred to herein as “toes”) and in areas between the two seals. The term “toe” is not intended to be limiting to any particular shape necessarily. It is intended to include within its ambit a curved toe having an arcuate outline of the type defined by a dovetail gland for example, as well as a rectangular toe such as a square corner defined by a rectangular groove, for example. Other toe shapes are possible, and may include obtuse or acute corners, for example. In any event, air trapped within a toe or other volume is sought to be vented to prevent virtual leaks. One challenge therein is that the provision of direct-venting features would expose the vacuum seal to the chemistry, defeating the purpose of the barrier seal.

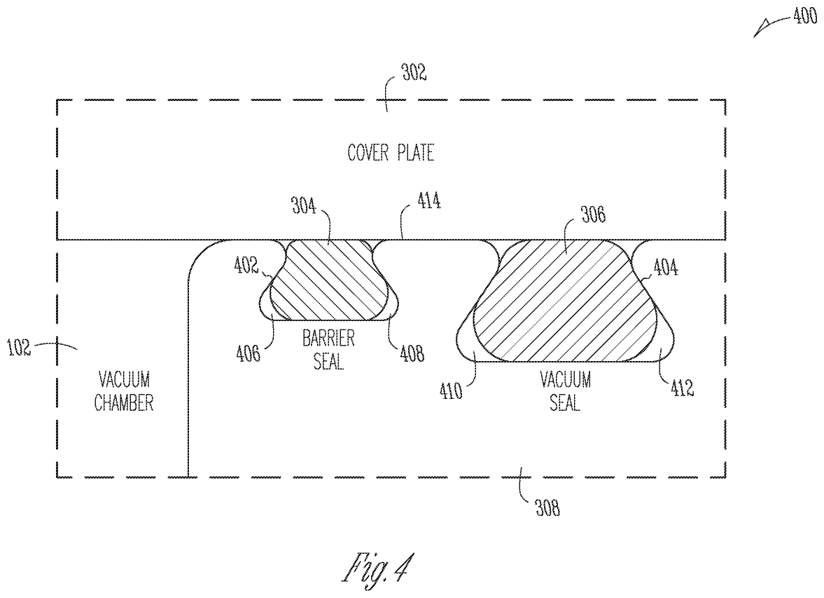

FIG. 4 is a sectional view of the barrier seal 304 and the vacuum seal 306 illustrated in FIG. 3. Each seal lies in a respective gland, or groove, formed in the side wall 308. The harrier seal 304 lies in the barrier seal gland 402. In this example, the barrier seal gland 402 is a full dovetail gland that includes two toes accordingly, an inner toe 406 and an outer toe 408. The vacuum seal gland 404 in this example is also a full dovetail gland and includes an inner toe 410 and an outer toe 412. Either gland may be a half dovetail gland in some examples. Other gland configurations, such as a simple rectangular groove, are possible. A thin space at the parting line of the cover plate 302 and the side wall 308 is represented by a line 414 in FIG. 4. The thin space 414 has some volume, albeit small, and extends radially outwardly between the barrier seal 304 and the vacuum seal 306, and thus also between the barrier seal gland 402 and the vacuum seal gland 404.

Undesired air can become trapped in the inner toe 406 and outer toe 408 of the barrier seal gland 402, and in the thin space 414, and also in at least the inner toe 410 of the vacuum seal gland 404. Unless vented, this trapped air can cause virtual leaks and cause at least some of the issues discussed herein. To this end, some examples herein provide a double seal arrangement that includes a first venting pathway between the inner toe of the vacuum seal gland and the outer toe of the barrier seal gland; a second venting pathway between the outer toe of the barrier seal gland and the inner toe of the harrier seal gland; and a third venting pathway between the inner toe of the barrier seal gland and a vacuum source. As will be explained more fully below, in some examples the venting pathways are provided at different locations around the periphery of the barrier seal gland 402 and the vacuum seal gland 404 to provide and define a constricted, long and tortuous venting passage for the trapped air that significantly impedes the passage of harmful radicals in the opposite direction.

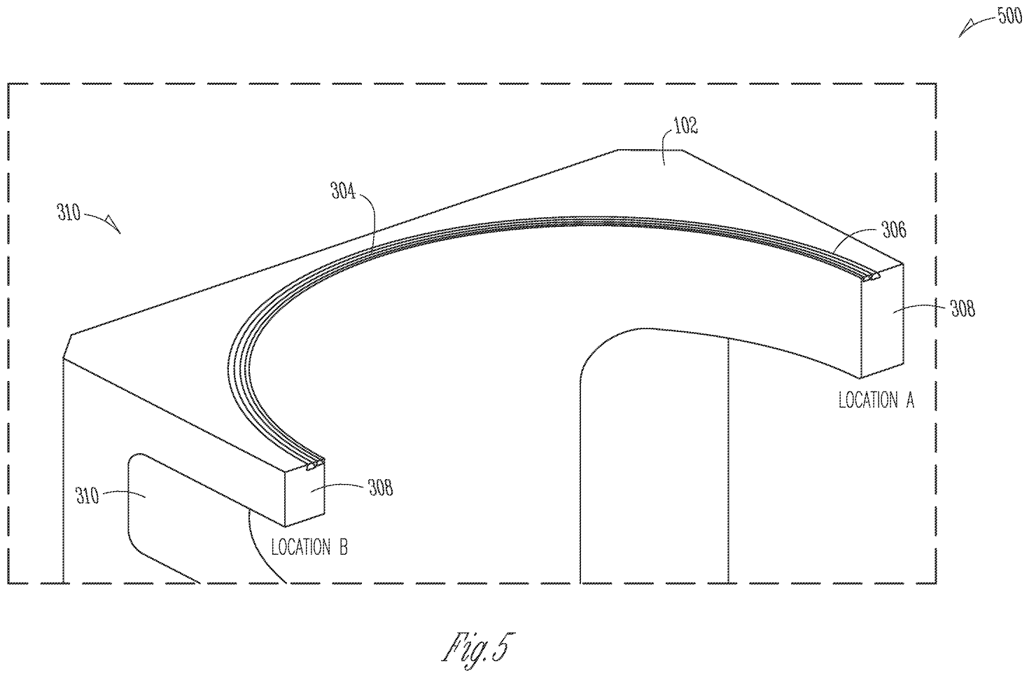

In this regard, an expanded sectional view of the processing chamber 102 is shown in FIG. 5. The inner barrier seal 304 and the outer vacuum seal 306 may again be seen. As explained above, these seals lie in a respective barrier seal gland 402 and a vacuum seal gland 404 formed in the side wall 308 of the processing chamber 102. For purposes of explanation, Locations A and B on opposite sides of the processing chamber 102, or at different points on the circumferences of the barrier seal gland 402 and the vacuum seal gland 404, are identified. In the illustrated example, the Locations A and B are at opposite sides of the barrier seal gland 402 and the vacuum seal gland 404 (or expressed another way, separated by a 180 degree separation angle in plan view). Other separation angles (or distances) for Locations A and B are possible, for example a separation angle of 90 degrees in either circumferential direction, or a separation angle of 45 degrees or 30 degrees apart. Either separation angles are possible. The circumferential positions and separation angles of Locations A and B can be selected to determine or adjust a configuration of a venting pathway or passage.

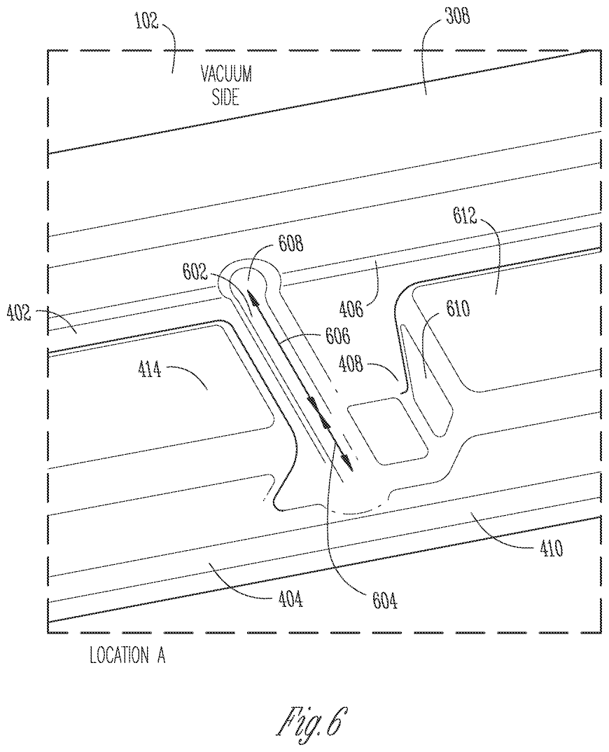

FIG. 6 shows a pictorial view 600 of first and second venting pathways provided at Location A. A vacuum side of the processing chamber 102 is shown adjacent the side wall 308. The barrier seal gland 402 and vacuum seal gland 404 are also visible. As described above, the barrier seal gland 402 includes an inner toe 406 and an outer toe 408. The vacuum seal gland 404 includes at least an inner toe 410. A base of the enclosed space 414 appears between the harrier seal gland 402 and the vacuum seal gland 404. A cross channel 602 or trench interconnects the inner toe 410 of the vacuum seal gland 404, the outer toe 408 of the barrier seal gland 402, and the inner toe 406 of the barrier seal gland 402. A first portion 604 of the cross channel 602 provides or defines a first venting pathway for air trapped inn the inner toe 410. A second portion 606 of the cross channel 602 provides or defines a second venting pathway for air trapped in the inner toe 410 and the outer toe 408 of the barrier seal gland 402.

In the illustrated example, the first and second venting pathways are coincident and defined by a common cross channel 602 at the Location A. In other examples, the first and second venting pathways may not be coincident or may be separately provided at different locations. The illustrated example cross channel 602 passes underneath the barrier seal 304 in use and includes a hollow recess 608 at an inner end thereof allowing, or created by, passage of a machining tool into the barrier seal gland 402 during formation of the cross channel 602. In some examples, the hollow recess 608 enhances access by vented air to the inner toe 406 at Location A. From that location, the vented air can travel around the circumference of the inner toe 406 in either direction to Location B. A third venting pathway (or escape) provided at Location B is described further below.

In some examples, a dimension of the cross channel 602 prevents closure thereof by the barrier seal 304 when the double seal arrangement is under vacuum, i.e., when the barrier seal 304 is compressed. In other words, a depth (for example) of the cross channel 602 is selected in light of a known compressibility of the barrier seal 304 such that a compressed barrier seal 304 is not able to deform downwardly to fill the cross channel 602.

A gap 610 or notch provided in the center wall 612 between the barrier seal gland 402 and the vacuum seal gland 404 allows the enclosed. space 414 access to the cross channel 602 and the first or second venting pathways. The enclosed space 414 can be vented, accordingly. Thus, so far, an example venting passage is created by and includes the first and second pathways defined by the first portion 604 and second portion 606 of the cross channel 602 and the internal volume of the inner toe 406 arounds the semicircular periphery of the barrier seal gland 402 where the barrier seal gland 402 reaches Location B. The enclosed space 414 is provided access to that venting passageway, or parts of it along the way. Other numbers and/or configurations of venting passages and pathways are possible.

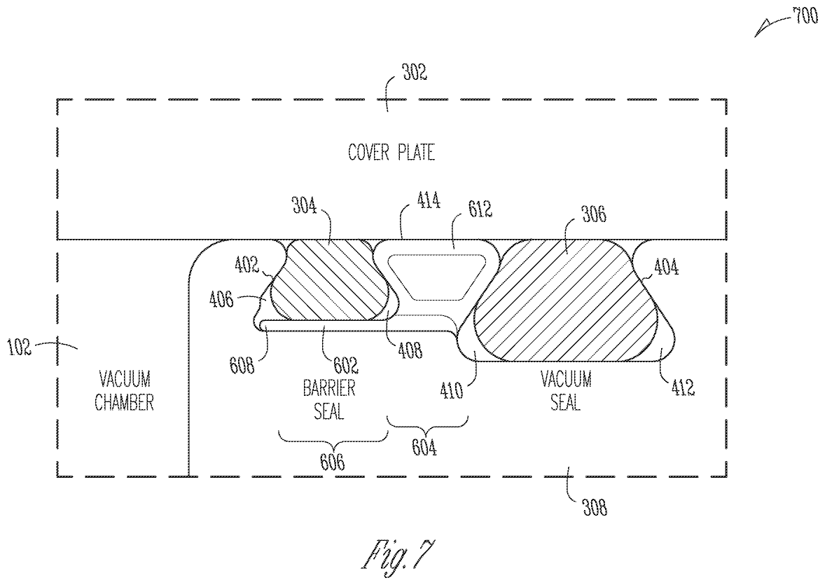

FIG. 7 shows a sectional view of the double seal arrangement described above with reference to FIG. 6. Corresponding parts have been given the same respective numerals.

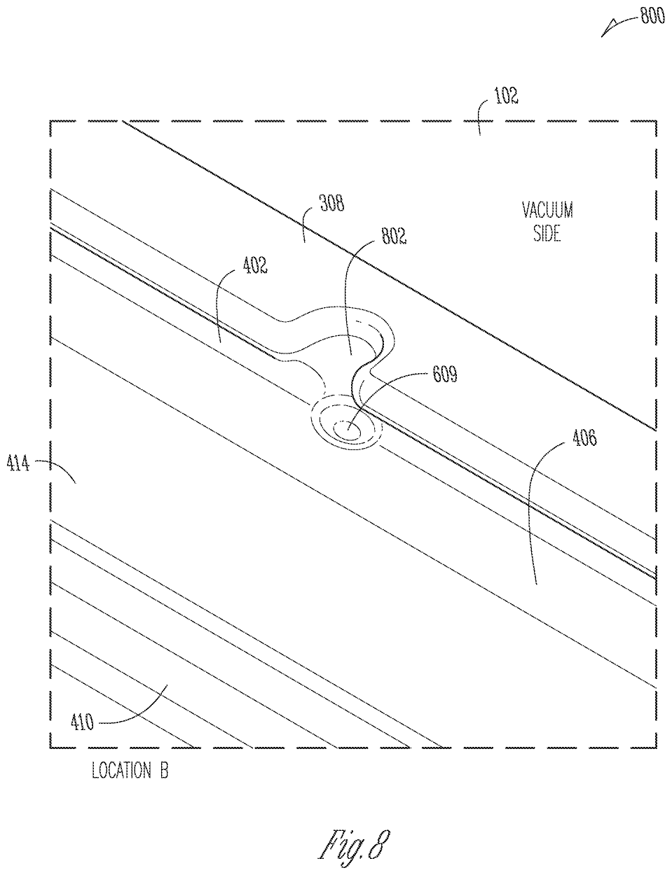

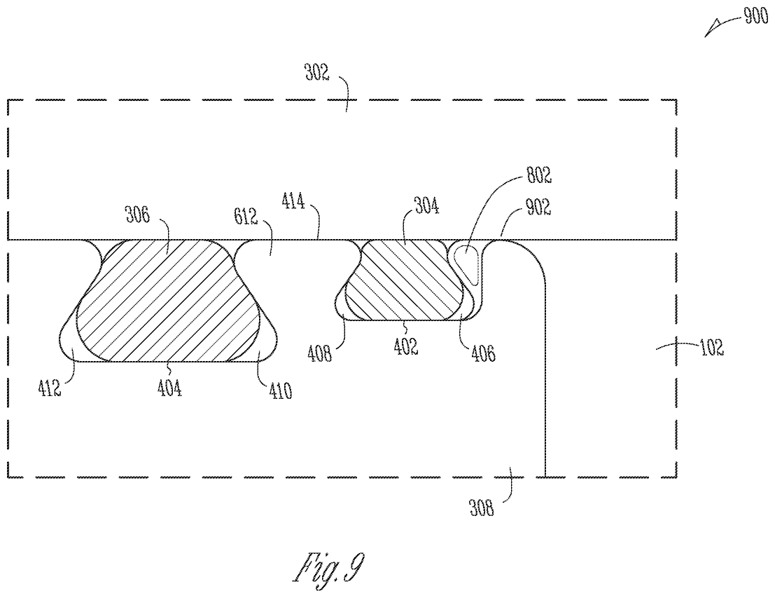

Reference is now made to FIG. 8 which provides a pictorial view 800 of the barrier seal gland 402 at Location B. In some examples, the vented air that has just traveled down all or part of the example venting passageway described above is allowed to exit into the vacuum chamber (processing chamber 102) at Location B. To this end, a third venting pathway is defined by or includes a venting port 802. The third venting pathway is provided between the inner toe 406 of the barrier seal gland 402 gland and the vacuum source (in this example, the processing chamber 102). Other locations for the venting port 802 around the barrier seal 304 or processing chamber 102 are possible. A location may be selected with a view to configuring an appropriately long, constrictive and/or tortuous venting passageway for given processing conditions, for example. In the illustrated example, vented air passes into the venting port 802 via a second hollow recess 609 and into the processing chamber 102 over the top of the side wall 308. As shown more clearly in FIG. 9, there is no barrier to the vented air in the air gap 902 between the top of the side wall 308 and the cover plate 302 in the region between the venting port 802 and the processing chamber 102. It is the outer barrier seal 304 and vacuum seal 306 that provide a sealing function as discussed as further above.

FIG. 9 shows a sectional view 900 of the double seal arrangement described above with reference to FIG. 8. Corresponding parts have been given the same respective numerals.

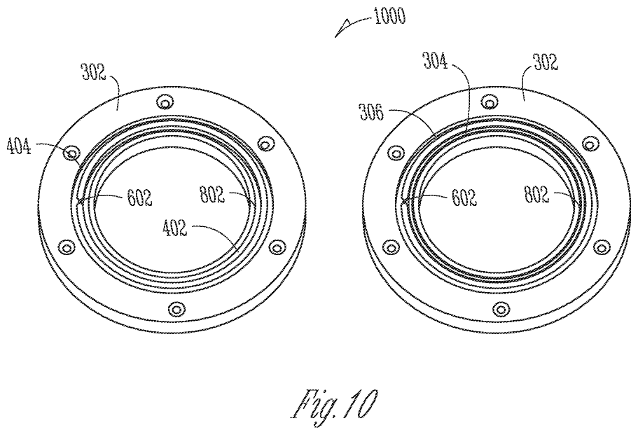

FIG. 10 includes perspective views 1000 of the underside of a cover plate 302. The barrier seal gland 402 and vacuum seal gland 404 are visible in the left view. The barrier seal 304 and the vacuum seal 306 installed therein are shown in the right view. The cross channel 602 and the venting port 802 are visible in both views.

In some examples, the vacuum source includes or is generated by the processing chamber 102, as described above. In some examples, a venting pathway or passageway is connected to or includes an exhaust line 118 of the processing chamber 102 . In some examples, a venting pathway or passageway is connected to or includes an external vacuum source, such as a vacuum pump. As mentioned above, other numbers and/or configurations of venting passages and pathways are possible. In this regard, a venting pathway or passageway may include vacuum retarding means or obstructions that add complexity, length, or constriction to the pathway or passageway. An example venting passageway may include a tubular venting pathway in which a vacuum retarding means includes a threaded screw. A space between the threads of the screw and the walls of the tubular pathway serve to add a spiral portion to the venting pathway or passageway. Other configurations are possible. In some examples, a second vacuum source is connected directly to the first or second venting pathways, in addition to or instead of the vacuum source being connected to the third venting passageway. In view of the aggressive nature of the processing chemistry being managed by the present examples, a wall of the barrier seal gland 402 and the vacuum seal gland 404 may include an anodized aluminum material. The profiles of these features may be smoothly rounded to minimize the creation of corrosion or stress points.

Thus, in some examples, a double seal arrangement is provided which creates a constrictive, long and tortuous venting passage in which process chemistry is unable to travel (or is significantly impeded from traveling) backstream to the vacuum seal 306. As described herein, one or more venting pathways are provided to establish a venting passage that is sufficiently constrictive, long and tortuous that the probability of radicals reaching the vacuum seal before recombination becomes exceedingly low. In the illustrated examples, a full venting passageway, viewed overall, may include first and second pathways defined by the first portion 604 and second portion 606 of the cross channel 602, and the internal volume of the inner toe 406 around the semicircular periphery of the barrier seal gland 402 at the point that the barrier seal gland 402 reaches Location B. At Location B, the venting passageway proceeds to include the third venting pathway defined by the venting port 802 and thence to the processing chamber 102. Further or other venting pathways are possible.

Although examples have been described with reference to specific example embodiments or methods, it will be evident that various modifications and changes may be made to these embodiments without departing from the broader scope of the embodiments. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This detailed description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

What is claimed is:

1. A double seal arrangement for a substrate processing chamber, the arrangement comprising:
a radially inner barrier seal disposed within a barrier seal gland, the barrier seal gland including an inner toe and an outer toe;
a radially outer vacuum seal disposed within a vacuum seal gland, the vacuum seal gland including at least an inner toe;
a first venting pathway between the inner toe of the vacuum seal gland and the outer toe of the barrier seal gland;
a second venting pathway between the outer toe of the barrier seal gland and the inner toe of the barrier seal gland;
a third venting pathway in communication at least with the inner toe of the barrier seal gland; and
a vacuum source connected to at least one of the first, second, and third venting pathways.

2. The double seal arrangement of claim 1, wherein the second venting pathway includes a cross channel passing underneath the barrier seal.

3. The double seal arrangement of claim 1, wherein the first and second vent pathways include or are defined by a common cross channel extending between the vacuum seal gland and the barrier seal gland, the cross channel passing underneath a lower surface of the barrier seal at a first circumferential location of the barrier seal gland.

4. The double seal arrangement of claim 3, wherein a dimension of the cross channel prevents closure thereof by the harrier seal when the double seal arrangement is under vacuum.

5. The double seal arrangement of claim 3, wherein the cross channel includes a recess permitting access by a machining tool into the harrier seal gland during formation of the cross channel.

6. The double seal arrangement of claim 3, wherein the third venting pathway includes or is defined by a venting port provided at a second circumferential location of the barrier seal gland.

7. The double seal arrangement of claim 1, wherein the first and second venting pathways are provided at a common location, and the third venting pathway is provided at a separate location.

8. The double seal arrangement of claim 1, wherein the second and third venting pathways are provided at a common location, and the first venting pathway is provided at a separate location.

9. The double seal arrangement of claim 1, wherein the first, second and third venting pathways are each provided at a separate location.

10. The double seal arrangement of claim 1, wherein the first and second venting pathways are provided at respective separate locations on the respective barrier and vacuum seal glands.

11. The double seal arrangement of claim 10, wherein the third venting pathway is provided at a respective separate location with respect to the first and second venting pathways.

12. The double seal arrangement of claim 1, wherein the vacuum source includes or is generated by the processing chamber.

13. The double seal arrangement of claim 1, wherein the vacuum source includes an exhaust line of the processing chamber.

14. The double seal arrangement of claim 1, wherein the vacuum source includes an external vacuum source.

15. The double seal arrangement of claim 1, further comprising a vacuum retarding means disposed in any one or more of the first, second, and third venting pathways.

16. The double seal arrangement of claim 15, wherein the vacuum retarding means includes a thread screw or tortuous path.

17. The double seal arrangement of claim 1, wherein a wall of the barrier seal gland or the vacuum seal gland includes an anodized aluminum material.

18. An apparatus for providing a double seal arrangement for a substrate processing chamber, the apparatus comprising:
a radially inner barrier seal gland for receiving a barrier seal therein, the barrier seal gland including an inner toe and an outer toe;
a radially outer vacuum seal gland for receiving a vacuum seal therein, the vacuum seal gland including at least an inner toe:
a first venting pathway between the inner toe of the vacuum seal gland and the outer toe of the barrier seal gland;
a second venting pathway between the outer toe of the barrier seal gland and the inner toe of the barrier seal gland; and
a third venting pathway between the inner toe of the barrier seal gland and a vacuum source.

19. The apparatus of claim 18, wherein the apparatus is defined by a single component.

20. The apparatus of claim 18, wherein the apparatus is defined by multiple components.

21. The apparatus of claim 18, further comprising a barrier seal and a vacuum seal.

22. A processing chamber comprising:
a double seal arrangement, the double seal arrangement comprising:
a radially inner barrier seal disposed within a barrier seal gland, the barrier seal gland including an inner toe and an outer toe;
a radially outer vacuum seal disposed within a vacuum seal gland, the vacuum seal gland including at least an inner toe;
a first venting pathway between the inner toe of the vacuum seal gland and the outer toe of the barrier seal gland;
a second venting pathway between the outer toe of the barrier seal gland and the inner toe of the barrier seal gland;
a third venting pathway in communication at least with the inner toe of the barrier seal gland; and
a vacuum source connected to at least one of the first; second, and third venting pathways.
